(19) United States
(12) Patent Application Publication
(10) Pub. No.: US 2005/0180481 A1
(43) Pub. Date: Aug. 18, 2005

(54) Surface-emitting semiconductor laser and method of manufacturing the same

(75) Inventors: Tsuyoshi Kaneko, Shimosuwa-machi (JP); Takeo Kaneko, Matsumoto-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/050,801

(22) Filed: Feb. 7, 2005

(30) Foreign Application Priority Data
Feb. 16, 2004 (JP) 2004-038519

(51) Int. Cl. H01S 5/00

(52) U.S. Cl. 372/50.21

(57) ABSTRACT

To provide a high speed surface-emitting semiconductor laser including a photo-detector, which has some degrees of freedom in its structure, and a method of manufacturing the same. A surface-emitting semiconductor laser according to the present invention includes a light-emitting device and a photo-detector formed on the light-emitting device. The light-emitting device includes a first mirror, an active layer formed on the first mirror, and a second mirror formed on the active layer. The second mirror is a multi-layered film. At least one of layers composing the unit period of the second mirror is a dielectric layer.

### BACKGROUND

The present invention relates to a surface-emitting semiconductor laser and a method of manufacturing the same.

Surface-emitting semiconductor lasers have a characteristic that an optical output is varied according to environmental temperature. On this account, optical modules employing such surface-emitting semiconductor lasers may have an optical detecting function for monitoring the optical output by detecting a portion of laser beams emitted from the surface-emitting semiconductor lasers. For example, photo-detectors provided in the surface-emitting semiconductor lasers, such as photodiodes, can monitor a portion of laser beams emitted from the surface-emitting semiconductor lasers (for example, see Patent Document 1 listed below). However, when the photo-detectors are provided in the surface-emitting semiconductor lasers, structures of the surface-emitting semiconductor lasers have a limitation in respect of polarities of layers constituting a part (light-emitting devices) contributing to generation of laser beams or photo-detectors, or structures of electrodes of the light-emitting devices and the photo-detectors. Such a limitation may lead to the decrease of the degree of freedom of the structures of the surface-emitting semiconductor lasers.

The surface-emitting semiconductor lasers, which can be operated at a high speed, are being applied to electronic devices or optical communication systems. Accordingly, it is required for the surface-emitting semiconductor lasers having the photo-detectors to be operated at a high speed.

Hereinafter, by way of an example, a structure of a surface-emitting semiconductor laser 900 having a conventional photo-detector will be described with reference to FIG. 21 (for example, see Patent Documents 2 and 3 listed below). FIG. 21 is a schematic sectional view illustrating the conventional surface-emitting semiconductor laser 900.

The surface-emitting semiconductor laser 900, as shown in FIG. 21, includes a light-emitting device 940 and a photo-detector 920, for example. The light-emitting device 940 is formed on a semiconductor substrate 901 and is composed of a first n-type mirror 902, an active layer 903, and a second p-type mirror 904, which are stacked in order. The photo-detector 920 is formed on the light-emitting device 940 and is composed of a first n-type contact layer 911, an impurity non-doped light absorbing layer 912, and a second p-type contact layer 913, which are stacked in this order. In addition, first and second electrodes 907 and 909 for driving the light-emitting device 940 and third and fourth electrodes 916 and 917 for driving the photo-detector 920 are provided.

In addition, a dielectric layer 915 is provided between the light-emitting device 940 and the photo-detector 920. The dielectric layer 915 comprises a layer containing aluminum oxide, for example. The dielectric later 915 is formed by oxidizing a layer (not shown) containing aluminum (Al) from a sidewall of the layer.

In the surface-emitting semiconductor laser 900, a voltage is applied between the first electrode 907 and the second electrode 909 in order to drive the light-emitting device 940. Also, a voltage is applied between the third electrode 916 and the fourth electrode 910 in order to drive the photo-detector 920.

As described above, the dielectric later 915 is formed by oxidizing the layer containing aluminum (Al). When the dielectric layer 915 is formed in this way, the layer containing aluminum (Al) before being oxidized is sparsely formed such that oxygen is easily implanted into the layer when the layer is oxidized. Accordingly, the dielectric layer 915 obtained by the oxidation is also sparse, which may result in deterioration of reliability and mechanical strength of the dielectric layer 915. Accordingly, in order to enhance the reliability and mechanical strength of the dielectric layer 915, it is necessary to form the dielectric layer 915 with a thin film thickness. However, if the dielectric layer 915 with a thin film thickness is provided between the light-emitting device 940 and the photo-detector 920, a large parasite capacitance occurs between the light-emitting device 940 and the photo-detector 920. This parasite capacitance prevents the surface-emitting semiconductor laser from driving at a high speed.
[Patent Document 1] Japanese Unexamined Patent Application Publication No. 10-135568.
[Patent Document 2] PCT Japanese Translation Patent Publication No. 2002-504754.
[Patent Document 3] Japanese Unexamined Patent Application Publication No. 2000-183444.

### SUMMARY

It is an object of the present invention to provide a high speed surface-emitting semiconductor laser including a photo-detector, which has some degrees of freedom in its structure, and a method of manufacturing the same.

In order to achieve the above-mentioned object, the present invention provides a surface-emitting semiconductor laser comprising: a light-emitting device; and a photo-detector formed on the light-emitting device, wherein the light-emitting device comprises a first mirror, an active layer formed on the first mirror, and a second mirror formed on the active layer, the second mirror is a multi-layered film, and at least one of the layers composing a unit period of the second mirror is a dielectric layer.

In the surface-emitting semiconductor laser according to the present invention, another particular element (B) formed on one particular element (A) includes B formed right on A, and B formed on A with a different element interposed therebetween. The definition of ‘on’ in the specification is also true of a method of manufacturing a surface-emitting semiconductor laser according to the present invention.

In the surface-emitting semiconductor laser, the second mirror is formed between the light-emitting device and the photo-detector. The second mirror is a multi-layered mirror, and at least one of layers composing the unit period of the second mirror is a dielectric layer. Accordingly, the light-emitting device can be isolated from the photo-detector by the second mirror. That is, in the surface-emitting semiconductor laser, the second mirror can act as the multi-layered mirror required for laser oscillation in the light-emitting device, and moreover, can act as an isolating layer for isolating the light-emitting device from the photo-detector.

In the surface-emitting semiconductor laser according to the present, a third mirror is formed between the active layer and the second mirror, and the third mirror is a multi-layered mirror composed of a semiconductor layer.

In the surface-emitting semiconductor laser according to the present invention, wherein the dielectric layer is a layer containing aluminum oxide, the at least one of the layers composing the unit period of the second mirror is an AlGaAs layer, and the third mirror includes at least two AlGaAs layers having different Al composition.

In the surface-emitting semiconductor laser according to the present invention and a method of manufacturing the same, Al composition of the AlGaAs layer refers to composition of aluminum (Al) for gallium (Ga). In the surface-emitting semiconductor laser according to the present invention and a method of manufacturing the same, Al composition of the AlGaAs layer has a range of 0 to 1. That is, the AlGaAs layer includes a GaAS layer (Al composition of 0) and an AlAs layer (Al composition of 1).

The surface-emitting semiconductor laser according to the present invention further comprises a first electrode and a second electrode for driving the light-emitting device, wherein the second electrode contacts with the third mirror.

In the surface-emitting semiconductor laser according to the present invention, the film thickness of the second mirror is more than 0.9 μm.

In the surface-emitting semiconductor laser according to the present invention, the Al composition of the AlGaAs layer composing the second mirror is less than 0.8.

In the surface-emitting semiconductor laser according to the present invention, the second mirror has a pillar shape, and a sidewall of the second mirror is covered with an insulating layer.

In the surface-emitting semiconductor laser according to the present invention, the insulating layer is made of resin.

In the surface-emitting semiconductor laser according to the present invention, the third mirror has a current limitation layer.

In the surface-emitting semiconductor laser according to the present invention, the photo-detector comprises: a first contact layer; a light absorbing layer formed on the first contact layer; and a second contact layer formed on the light absorbing layer.

The surface-emitting semiconductor laser according to the present invention further comprises a third electrode and a fourth electrode for driving the photo-detector.

In the surface-emitting semiconductor laser according to present invention, one of the first electrode and the second electrode is electrically connected to one of the third electrode and the fourth electrode at an electrode junction.

In the surface-emitting semiconductor laser according to the present invention, the electrode junction is formed in a region extending to an electrode pad, except for the light-emitting device and the photo-detector.

In addition, the present invention provides a method of manufacturing a surface-emitting semiconductor laser including a light-emitting device and a photo-detector formed on the light-emitting device and having an output surface, the method comprising: a step of laminating semiconductor layers to form at least a first mirror, an active layer, a second mirror composed of a multi-layered film, a first contact layer, a light absorbing layer, and a second contact layer on a substrate; a step of forming a first pillar-like portion including at least a part of the second contact layer by etching the semiconductor layers; a step of forming a second pillar-like portion including at least a part of the second mirror by etching the semiconductor layers; and a step of forming a dielectric layer by oxidizing at least one of the semiconductor layers composing a unit period of the second mirror from a sidewall of the at least one of the semiconductor layers.

In the method according to the present invention, the dielectric layer is formed by oxidizing an AlAs layer or an AlGaAs layer in the second mirror from a sidewall of the AlAs layer or the AlGaAs layer.

In the method according to the present invention, the step of laminating semiconductor layers includes a step of laminating other semiconductor layers to form a third mirror composed of a multi-layered film between the active layer and the second mirror, and the method further comprises a step of forming a third pillar-like portion including at least a part of the third mirror by etching the other semiconductor layers.

The method according to the present invention further comprises a step of forming a current limitation layer by oxidizing the semiconductor layers in the third mirror from sidewalls of the semiconductor layers.

In the method according to the present invention, the step of forming the dielectric layer and the step of forming the current limitation layer are performed by the same process.

The method according to the present invention further comprises a step of forming an insulating layer to cover a sidewall of the second pillar-like portion.

### BRIEF DESCRIPTION OF THE DRAWINGS

FIG. 1 is a schematic sectional view illustrating a surface-emitting semiconductor laser according to an embodiment of the present invention;

FIG. 2 is a schematic plan view illustrating the surface-emitting semiconductor laser according to the embodiment of the present invention;

FIG. 3 is a schematic sectional view illustrating a manufacturing process of the surface-emitting semiconductor laser according to the embodiment of the present invention;

FIG. 4 is a schematic sectional view illustrating a first manufacturing process of a surface-emitting semiconductor laser according to an embodiment of the present invention;

FIG. 5 is a schematic sectional view illustrating a manufacturing process of the surface-emitting semiconductor laser according to the embodiment of the present invention;

FIG. 6 is a schematic sectional view illustrating a manufacturing process of the surface-emitting semiconductor laser according to the embodiment of the present invention;

FIG. 7 is a schematic sectional view illustrating a manufacturing process of the surface-emitting semiconductor laser according to the embodiment of the present invention;

FIG. 8 is a schematic sectional view illustrating a manufacturing process of the surface-emitting semiconductor laser according to the embodiment of the present invention;

FIG. 9 is a schematic sectional view illustrating a manufacturing process of the surface-emitting semiconductor laser according to the embodiment of the present invention;

FIG. 10 is a schematic view illustrating a connection method of each electrode in a surface-emitting semiconductor laser according to an embodiment of the present invention;

FIG. 11 is a schematic view illustrating a connection method of each electrode in the surface-emitting semiconductor laser according to the embodiment of the present invention;

FIG. 12 is a schematic view illustrating a connection method of each electrode in the surface-emitting semiconductor laser according to the embodiment of the present invention;

FIG. 13 is a schematic view illustrating a connection method of each electrode in the surface-emitting semiconductor laser according to the embodiment of the present invention;

FIG. 14 is a schematic plan view illustrating a structure of each electrode in the surface-emitting semiconductor laser according to the embodiment of the present invention, when the connection method of FIG. 10 is used;

FIG. 15 is a schematic sectional view taken along line A-A in the surface-emitting semiconductor laser of FIG. 14;

FIG. 16 is a schematic sectional view taken along line B-B in the surface-emitting semiconductor laser of FIG. 14;

FIG. 17 is a schematic sectional view taken along line C-C in the surface-emitting semiconductor laser of FIG. 14;

FIG. 18 is a schematic plan view illustrating a structure of each electrode in the surface-emitting semiconductor laser according to the embodiment of the present invention, when the connection method of FIG. 11 is used;

FIG. 19 is a schematic plan view illustrating a structure of each electrode in the surface-emitting semiconductor laser according to the embodiment of the present invention, when the connection method of FIG. 12 is used;

FIG. 20 is a schematic plan view illustrating a structure of each electrode in the surface-emitting semiconductor laser according to the embodiment of the present invention, when the connection method of FIG. 13 is used; and

FIG. 21 is a schematic sectional view illustrating an example of a conventional surface-emitting semiconductor laser.

### DETAILED DESCRIPTION OF EMBODIMENTS

Hereinafter, preferred embodiments of the present invention will be described with reference to the accompanying drawings.

1. Structure of Surface-Emitting Semiconductor Laser

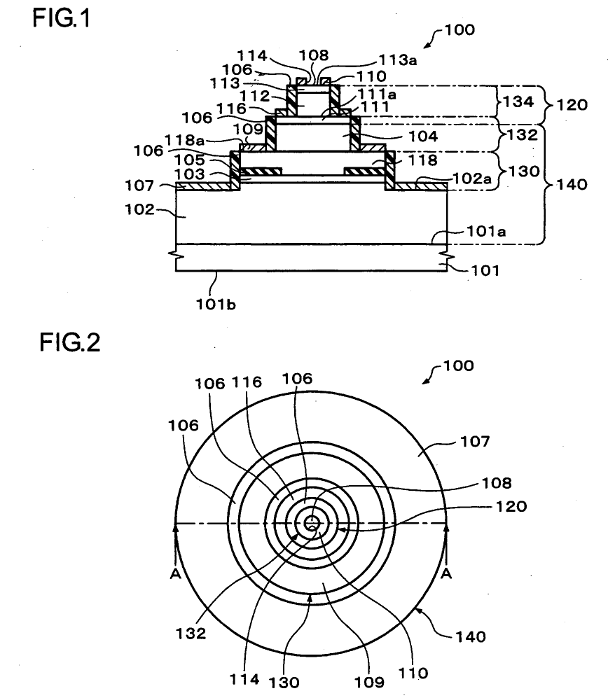

FIG. 1 is a schematic sectional view illustrating a surface-emitting semiconductor laser (hereinafter, abbreviated as ‘surface-emitting laser’) 100 according to an embodiment of the present invention. FIG. 2 is a schematic plan view illustrating the surface-emitting laser 100 of FIG. 1.

As shown in FIG. 1, the surface-emitting laser 100 according to this embodiment includes a light-emitting device 140 and a photo-detector 120. In the surface-emitting laser 100, a laser beam is generated in the light-emitting device 140 and is outputted through an output surface 108 provided on the photo-detector 120. In addition, the photo-detector 120 has a function to convert a portion of the laser beam generated in the light-emitting device 140 into current. Hereinafter, structures of the light-emitting device 140 and the photo-detector 120, and the entire structure of the surface-emitting laser 100 will be described.

1-1. Light-Emitting Device

The light-emitting device 140 is provided on a semiconductor substrate (n-type GaAs substrate in this embodiment) 101. The light-emitting device 140 constitutes a vertical resonator (hereinafter, abbreviated as ‘resonator’). In addition, the light-emitting device 140 may include a first pillar-like semiconductor deposit (hereinafter, referred to as ‘third pillar-like portion) 130 and a part of a second pillar-like semiconductor deposit (hereinafter, referred to as ‘second pillar-like portion’) 132.

The light-emitting device 140 includes forty pairs of distributed reflection-type multi-layer mirrors (hereinafter, referred to as ‘first mirror’) 102 having an n-type Al_{0.9}Ga_{0.1}As layer and an n-type Al_{0.15}Ga_{0.85}As layer, which are alternately stacked, an active layer 103 comprising a GaAs well layer and an Al_{0.3}Ga_{0.7}As barrier layer, the well layer including a three-layer quantum well structure, sixteen pairs of distributed reflection-type multi-layer mirrors 118 having an n-type Al_{0.9}Ga_{0.1}As layer and an n-type Al_{0.15}Ga_{0.85}As layer, which are alternately stacked, and five pairs of distributed reflection-type multi-layer mirrors 104 having an undoped Al_{0.2}Ga_{0.8}As layer and a dielectric layer, which are alternately stacked, for example, which are stacked in order. As the dielectric layer, for example, a layer containing aluminum oxide (AlOₓ) may be used. In this embodiment, a case where the layer containing the aluminum oxide is used as the dielectric layer will be described. The five pairs of distributed reflection-type multi-layer mirrors 104 having the undoped Al_{0.2}Ga_{0.8}As layer and the layer containing the aluminum oxide, which are alternately stacked, is hereinafter referred to as a second mirror. In addition, the sixteen pairs of distributed reflection-type multi-layer mirrors 118 having the n-type Al_{0.9}Ga_{0.1}As layer and the n-type Al_{0.15}Ga_{0.85}As layer, which are alternately stacked, is hereinafter referred to as a third mirror.

In the surface-emitting laser 100 according to this embodiment, the second mirror 104 has a unit period composed of two layers, i.e., the undoped Al_{0.2}Ga_{0.8}As layer and the dielectric layer. The unit period of the second mirror 104 may composed of at least one dielectric layer.

Although Al composition of the undoped Al_{0.2}Ga_{0.8}As layer in the second mirror 104 is 0.2 in this embodiment, it may be less than 0.8, for example. Although Al composition of the n-type Al_{0.9}Ga_{0.1}As layer having higher Al composition in the third mirror 118 is 0.9 in this embodiment, it may be more than 0.8, for example. Although Al composition of the n-type Al_{0.15}Ga_{0.85}As layer having smaller Al composition in the third mirror 118 is 0.15 in this embodiment, it may be less than 0.2, for example.

However, the composition of each layer constituting the first mirror 102, the active mirror 103, the second mirror 104, and the third mirror 118, and the number of layers are not limited to this.

For example, the third mirror 118 may be of a p-type by doping carbon (C), zinc (Zn), and so forth, and the first mirror 102 may be of an n-type by doping silicon (Si), selenium (Se), and so forth. Accordingly, a pin diode may be formed by the third mirror 118 of the p-type, the active layer 103 undoped with impurities, the first mirror 102 of the n-type.

Of the light-emitting device 140, a part spanning from the third mirror 118 up to an upper portion of the first mirror 102 is etched into a circular shape, when viewed from a direction perpendicular to the output surface 108, to form the third pillar-like portion 130. Although a plane surface of the third pillar-like portion 130 is shown to have a circular shape in the surface-emitting laser 100, it may take any shape.

Of the photo-detector 120, which will be described later, a part spanning from a first contact layer 111 up to the second mirror 104 of the light-emitting device 140 is etched into a circular shape, when viewed from the direction perpendicular to the output surface 108, to form the second pillar-like portion 132. Although a plane surface of the second pillar-like portion 132 is shown to have a circular shape in the surface-emitting laser 100, it may take any shape.

Insulating layers 106, each of which is made of polyimide-series resin, are formed around the second pillar-like portion 132, the above-described third pillar-like portion 130, and a first pillar-like portion 134, which will be described later. Although the insulating layers 106 are made of the polyimide-series resin in the surface-emitting laser 100 of this embodiment, any insulating material including other resin material, such as acryl-series resin or epoxy-series resin, or inorganic dielectric films, such as a silicon oxide film or silicon nitride film, may be used.

The second mirror 104 contacts with the photo-detector 120 (more particularly, the first contact layer 111 of the photo-detector 120). In the surface-emitting laser 100, when cut at a plane in parallel with a surface 101a of the semiconductor substrate 101, a cross section of the third mirror 118 is larger than that of the second mirror 104, as shown in FIGS. 1 and 2. Accordingly, in the light-emitting device 140, a step is formed between the third pillar-like portion 130 and the second pillar-like portion 132. That is, the second pillar-like portion 132 is formed on a part of a top surface 118a of the third pillar-like portion 130. A second electrode 109, which will be described later, is additionally formed on the top surface 118a of the third pillar-like portion 130.

In addition, in the third mirror 118, a current limitation layer 105 made of aluminum oxide is formed at a region near the active layer 103. The current limitation layer 105 is formed in a ring shape. Namely, when cut at a plane in parallel with the surface 101a of the semiconductor substrate 101, as shown in FIG. 1, the current limitation layer 105 has a cross section of a circular shape concentric with a plane of the third pillar-like portion 130.

In addition, a first electrode 107 and a second electrode 109 are provided in the light-emitting device 140. The first electrode 107 and the second electrode 109 are used to apply a voltage to the light-emitting device 140 to be drived. In more detail, as shown in FIG. 1, the first electrode 107 is provided on a top surface 102a of the first mirror 102 of the light-emitting device 140, and the second electrode 109 is provided on the top surface 118a of the third mirror 118 of the light-emitting device 140. In addition, as shown in FIG. 2, the first electrode 107 and the second electrode 109 have a plane of a ring shape. In addition, the first electrode 107 is provided in such a manner that it surrounds the third pillar-like portion 130, and the second electrode 109 is provided in such a manner that it surrounds the second pillar-like portion 132. In other words, the third pillar-like portion 130 is provided inside the first electrode 107 and the second pillar-like portion 132 is provided inside the second electrode 109.

In addition, although the first electrode 107 is shown to be provided on the first mirror 102 in this embodiment, it may be provided on a back surface 101b of the semiconductor substrate 101.

The first electrode 107 is composed of a laminating film including Au and an alloy of Au and Ge, for example. In addition, the second electrode 109 is composed of a laminating film including Pt and Au, for example. Current is applied to the active layer 103 by the first electrode 107 and the second electrode 109. Material used to the first electrode 107 and the second electrode 109 is not limited to this, but may be an alloy of Au and Zn, for example.

1-2. Photo-Detector

The photo-detector 120 is provided on the light-emitting device 140 and has the output surface 108. The photo-detector 120 may include a part of the second pillar-like portion 132 and a part of a pillar-like semiconductor deposit (hereinafter, referred to as ‘first pillar-like portion) 134.

The photo-detector 120 may include the first contact layer 111, a light absorbing layer 112, and a second contact layer 113, for example. The first contact layer 111 is provided on the second mirror 104 of the light-emitting device 140, the light absorbing layer 112 is provided on the first contact layer 111, and the second contact layer 113 is provided on the light absorbing layer 112. In addition, in the photo-detector 120 in this embodiment, an area of a plane of the first contact layer 111 is larger than areas of planes of the light absorbing layer 112 and the second contact layer 113 (See FIGS. 1 and 2).

Of the photo-detector 120, a part spanning from the second contact layer 113 up to the light absorbing layer 112 is etched into a circular shape, when viewed from a direction perpendicular to the output surface 108, to form the first pillar-like portion 134. Although a plane surface of the first pillar-like portion 134 is shown to have a circular shape in the surface-emitting laser 100, it may take any shape.

The first contact layer 111 is composed of an n-type GaAs layer, for example, the light absorbing layer 112 is composed of an impurity undoped GaAs layer, for example, and the second contact layer 113 is composed of a p-type GaAs layer, for example. In more detail, the first contact layer 111 is of n-type by doping silicon (Si), for example, and the second contact layer 113 is of p-type by doping carbon (C), for example. Accordingly, a pin diode is formed by the second contact layer 113 of the p-type, the light absorbing layer 112 undoped with impurities, and the first contact layer 111 of the n-type.

A third electrode 116 and a fourth electrode 110 are provided in the photo-detector 120. The third electrode 116 and the fourth electrode 110 are used to drive the photo-detector 120. In the surface-emitting laser 100 in this embodiment, the third electrode 116 may be made of the same material as the first electrode 107 and the fourth electrode 110 may be made of the same material as the second electrode 109.

The third electrode 116 is provided on the first contact layer 111. In other words, the first contact layer 111 contacts with the third electrode 116. The fourth electrode 110 is provided on the top surface (the second contact layer 113) of the photo-detector 120. An opening 114 is provided in the fourth electrode 110. The output surface 108 is a top surface 113a of the second contact layer 113 exposed through the opening 114. Accordingly, by properly setting the plane shape and size of the opening 114, the shape and size of the output surface 108 can be properly set. In this embodiment, the output surface 108 has a circular shape, as shown in FIG. 2.

1-3. Entire Configuration

The surface-emitting laser 100 in this embodiment entirely has an npnp structure composed of the first mirror 102 of the n-type and the third mirror 118 of the p-type in the light-emitting device 140, and the first contact layer 111 of the n-type and the second contact layer 113 of the p-type in the photo-detector 120. Namely, the surface-emitting laser 100 has two pn junctions. In addition, by exchanging p-type for n-type in each layer, a pnpn structure may be entirely formed.

The photo-detector 120 has a function of monitoring output of light generated in the light-emitting device 140. More specifically, the photo-detector 120 converts light generated in the light-emitting device 140 to current. The output of light generated in the light-emitting device 140 is detected by using a value of the current.

In more detail, in the photo-detector 120, some of light generated in the light-emitting device 140 is absorbed in the light absorbing layer 112, and, due to the absorbed light, photoexcitation occurs and electrons and holes are generated in the light absorbing layer 112. Then, the electrons move to the third electrode 116 and the holes move to the fourth electrode 110 by an electric field applied externally. As a result, in the photo-detector 120, current flows from the first contact layer 111 to the second contact layer 113.

In addition, the light output of the light-emitting device 140 is mainly determined by a bias voltage applied to the light-emitting device 140. In the surface-emitting laser 100, the light output of the light-emitting device 140 is greatly varied depending on environmental temperature or lifetime of the light-emitting device 140, as in general surface-emitting lasers. In the surface-emitting laser 100 according to this embodiment, the light output of the light-emitting device 140 can be monitored by the photo-detector 120. In other words, by adjusting a value of voltage applied to the light-emitting device 140 based on a value of current generated in the photo-detector 120, a value of current flowing through the light-emitting device 140 can be adjusted. Accordingly, a constant light output can be maintained in the light-emitting device 140. A feedback of the light output of the light-emitting device 140 on the value of voltage applied to the light-emitting device 140 can be conducted using an external electronic circuit (not shown) such as a driving circuit.

2. Operation of Surface-Emitting Laser

Hereinafter, a general operation of the surface-emitting laser 100 in this embodiment will be described. In the following description, a driving method of the surface-emitting laser 100 is provided as one example. However, the driving method may be modified in various ways without deviating from the spirit of the present invention.

To begin with, in the first electrode 107 and the second electrode 109, when a forward voltage is applied to a pin diode, recombination of electrons and holes is generated in the active layer 103 of the light-emitting device 140, and accordingly, light is emitted from the active layer 103. The emitted light is reflected by the first mirror 102, the second mirror 104, and the third mirror 118. When the emitted light goes and returns above and below the active layer 103, stimulated emission occurs and the intensity of light is amplified. When an optical gain exceeds an optical loss, laser oscillation occurs and laser light is generated in the active layer 103. The laser light is incident into the first contact layer 111 of the photo-detector 120 through the second mirror 104 of the light-emitting device 140.

Next, in the photo-detector 120, the laser light incident into the first contact layer 111 is then incident into the light absorbing layer 112. Some of the incident light is absorbed in the light absorbing layer 112, and consequently, the light excitation occurs in the light absorbing layer 112, and accordingly, electrons and holes are generated. Then, the electrons move to the third electrode 116 and the holes move to the fourth electrode 110 by an electric field applied externally. As a result, in the photo-detector 120, current (photocurrent) flows from the first contact layer 111 to the second contact layer 113. By measuring a value of the current, the light output of the light-emitting device 140 can be detected. The light passing through the photo-detector 120 is outputted from the output surface 108.

In the surface-emitting laser 100 according to this embodiment, since variation of light output due to temperature and the like can be corrected by monitoring some of the light output of the light-emitting device 140 with the photo-detector 120 and feedbacking the monitored light output to a driving circuit, a stable light output can be obtained.

3. Manufacturing Method of Surface-Emitting Semiconductor Laser

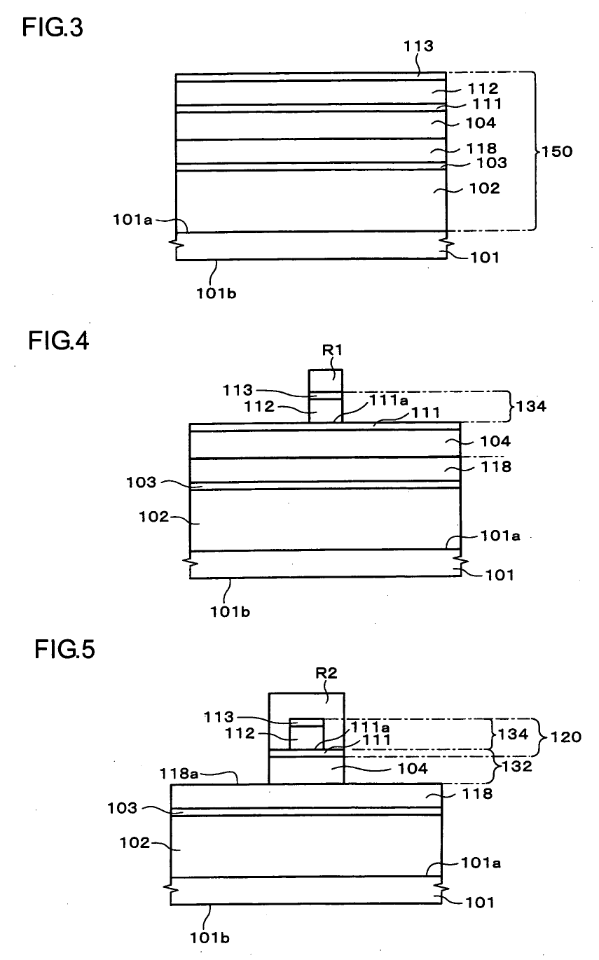

Next, one example of a manufacturing method of the surface-emitting laser 100 according to an embodiment of the present invention will be described with reference to FIGS. 3 to 9. FIGS. 3 to 9 are schematic sectional views illustrating a manufacturing process of the surface-emitting laser 100 as shown in FIGS. 1 and 2, and correspond to the sectional view shown in FIG. 1, respectively.

(1) To begin with, a semiconductor multi-layered film 150 is formed on a surface 101a of a semiconductor substrate 101 made of n-type GaAs, as shown in FIG. 3, by epitaxially growing while changing composition of the semiconductor substrate 101. Here, the semiconductor multi-layered film 150 includes forty pairs of first mirrors 102 having an n-type Al_{0.9}Ga_{0.1}As layer and an n-type Al_{0.15}Ga_{0.85}As layer, which are alternately stacked, an active layer 103 comprising a GaAs well layer and an Al_{0.3}Ga_{0.7}As barrier layer, the well layer including a three-layer quantum well structure, sixteen pairs of third mirrors 118 having a p-type Al_{0.9}Ga_{0.1}As layer and a p-type Al_{0.15}Ga_{0.85}As layer, which are alternately stacked, and five pairs of second mirrors 104 having an undoped Al_{0.2}Ga_{0.8}As layer and a layer which will be a dielectric layer in an oxidation process which will be described later, which are alternately stacked, a first contact layer 111 comprising an n-type GaAs layer, a light absorbing layer 112 comprising an impurity undoped GaAs layer, and a second contact layer 113 comprising a p-type GaAs layer, for example. The semiconductor multi-layered film 150 is formed by laminating theses layers on the semiconductor substrate 101 in order (See FIG. 3).

As the layer to be the dielectric layer in the second mirror 104, for example, an undoped AlGaAs layer or an AlAs layer can be employed. Al composition of the undoped AlGaAs layer to be employed as the layer to be the dielectric layer is properly set such that the entire layers are completely oxidized in a process for forming the dielectric layer, which will be described later.

In addition, when the third mirror 118 is grown, at least one layer in the vicinity of the active layer 103 is formed as an AlAs layer or an AlGaAs layer having Al composition of more than 0.95. This layer will be oxidized to be a current limitation layer 105 later (See FIG. 7).

In addition, when a second electrode 109 is formed in a subsequent process, it is preferable to increase carrier density in the vicinity of at least a portion of the third mirror 118 contacting with the second electrode 109 in order to easily make an ohmic contact with the second electrode 109. Similarly, it is preferable to increase carrier density in the vicinity of at least a portion of the first contact layer 111 contacting with the third electrode 116 and carrier density in the vicinity of at least a portion of the second contact layer 113 contacting with the fourth electrode 110 in order to easily make an ohmic contact with the third electrode 116 and the fourth electrode 110, respectively.

Temperature at which epitaxial growth is conducted is properly determined depending on a growth method, growth material, a kind of semiconductor substrate 101, or a kind and a thickness of the semiconductor multi-layered film 150 to be formed, and a carrier density. Generally, the temperature is preferably 450° C. to 800° C. In addition, time required for the epitaxial growth is properly determined in the same way as the temperature. As epitaxial growth methods, there are a metal-organic vapor phase epitaxy (MOVPE) method, a molecular beam epitaxy (MBE) method, a liquid phase epitaxy (LPE) method, etc.

(2) Next, a first pillar-like portion 134 is formed by patterning the second contact layer 113 and the light absorbing layer 112 into a certain shape (See FIG. 4). More specifically, a resist (not shown) is first coated on the semiconductor multi-layered film 150. Next, a resist layer R1 having a certain pattern is formed by patterning the resist using a lithography process.

Next, using the resist layer R1 as a mask, the second contact layer 113 and the light absorbing layer 112 are etched using, for example, a dry etching process or a wet etching process. Accordingly, the second contact layer 113 and the light absorbing layer 112 having the same plane shape as the second contact layer 113 are formed. Thereafter, the resist layer R1 is removed.

(3) Next, a second pillar-like portion 132 is formed by patterning the first contact layer 111 and the second mirror 104 into a certain shape (See FIG. 5). More specifically, a resist (not shown) is first coated at least on the first contact layer 111 and the second contact layer 113, and then, a resist layer R2 having a certain pattern is formed by patterning the resist using a lithography process (See FIG. 5).

Next, using the resist layer R2 as a mask, the first contact layer 111 and the second mirror 114 are etched using, for example, a dry etching process or a wet etching process.

Through the above-described processes, the photo-detector 120 is formed, as shown in FIG. 5. The photo-detector 120 includes the second contact layer 113, the light absorbing layer 112 and the first contact layer 111. In addition, in a plan view, an area of a plane shape of the first contact layer 111 can be formed to be larger than those of plane shapes of the second contact layer 113 and the light absorbing layer 112. Thereafter, the resist layer R1 is removed.

In the above processes, although a case where the first contact layer 111 is patterned after the second contact layer 113 and the light absorbing layer 112 are patterned has been described, the photo-detector 120 may be formed by patterning the second contact layer 113 and the light absorbing layer 112 after patterning the first contact layer 111.

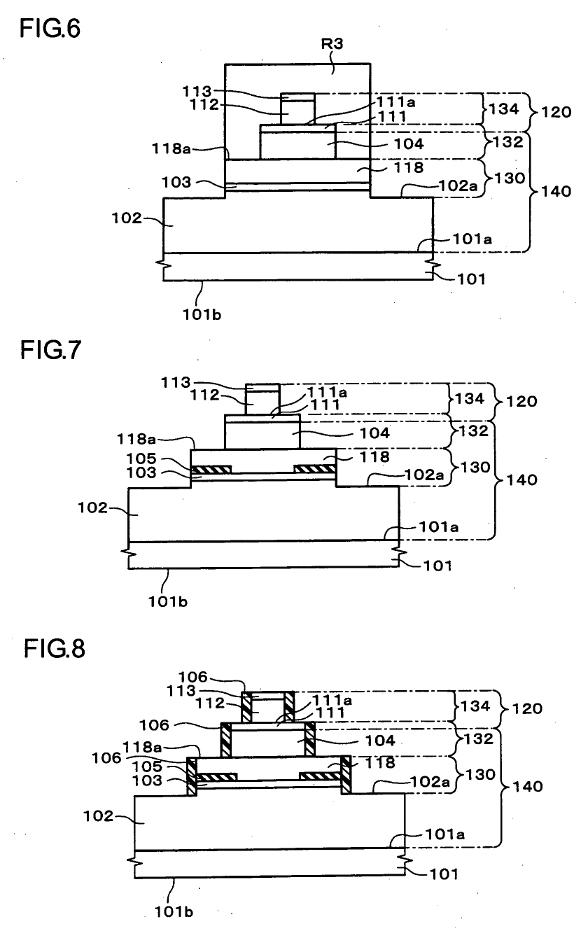

(4) Next, a third pillar-like portion 130 is formed by performing a patterning process (See FIG. 6). More specifically, a resist (not shown) is first coated on at least the third mirror 118, the first contact layer 111 and the second contact layer 113. Next, a resist layer R3 having a certain pattern is formed by patterning the resist using a lithography process (See FIG. 6).

Next, using the resist layer R3 as a mask, the third mirror 118, the active layer 103, and a part of the first mirror 102 are etched using, for example, a dry etching process or a wet etching process. Accordingly, the third pillar-like portion 130 is formed, as shown in FIG. 6. Through the above process, a resonator (the light-emitting device 140) including the third pillar-like portion 130 and a part of the second pillar-like portion 132 is formed on the semiconductor substrate 101. That is, a laminating structure including the photo-detector 120 and the light-emitting device 140 is formed. Thereafter, the resist layer R1 is removed.

The dry etching process employable in the process for forming the first pillar-like portion 134, the second pillar-like portion 132, and the third pillar-like portion 130 includes a plasma etching process using a gas containing chlorine or chloride. At this time, if necessary, another gas containing an inert gas such as argon, or fluoride may be added. In addition, the wet etching process employable in the process for forming the first pillar-like portion 134, the second pillar-like portion 132, and the third pillar-like portion 130 includes an etching process using hydrochloric acid, sulfuric acid, phosphoric acid, hydrofluoric acid, oxygenated water, ammonia water, ammonium fluoride solution, or a mixture thereof, which are selected according to property of material to be etched.

In addition, in this embodiment, as previously described, although a case where the light-emitting device 140 is formed after the photo-detector 120 is first formed has been described, the photo-detector 120 may be formed after the light-emitting device 140 is first formed.

(5) Subsequently, the semiconductor substrate 101 on which the light-emitting device 140 and the photo-detector 120 are formed through the above processes is put in a vapor atmosphere of about 400° C. As a result, as shown in FIG. 7, as a layer having large Al composition formed in the third mirror 118 through the above-described processes is oxidized from a side surface thereof, a current limitation layer 105 is formed. In addition, as a layer formed in the second mirror 104 through the above-described processes is oxidized from a side surface thereof, a dielectric layer is formed. In this embodiment, the dielectric layer is composed of five layers.

An oxidation rate depends on the temperature of a furnace, the amount of vapor supplied, and Al composition and film thickness of a layer to be oxidized. The layer (layer to be the current limitation layer) having large Al composition formed in the third mirror 118 can be oxidized such that the layer has a region which is not oxidized in a central portion of the layer, when viewed from the plane of the layer. However, the layer, which will be the dielectric layer, formed in the second mirror 104 can completely be oxidized entirely. More specifically, for example, Al composition of the layer having large Al composition formed in the third mirror 118 can be 0.97 and Al composition of the layer, which is will be the dielectric layer, formed in the second mirror 104 can be 1.0 (That is, the layer to be the dielectric layer is an AlAs layer). In addition, the film thickness of the layer to be oxidized is properly set such that the film thickness 105 of the current limitation layer 105 after oxidation is 10-30 nm and the film thickness of the dielectric layer is about 0.13 μm. In addition, the temperature of the furnace and the amount of vapor supplied are properly set.

In operating the surface-emitting laser having the current limitation layer formed by the oxidation, current flows into only a region where the current limitation layer is not formed (a non-oxidized region). Accordingly, in the process for forming the current limitation layer 105 by the oxidation, the density of current can be controlled by controlling a formation range of the current limitation layer 105.

In addition, it is preferable to adjust a diameter of an opening of the current limitation layer 105 such that most of light emitted from the light-emitting device 140 is incident into the first contact layer 111.

(6) Next, as shown in FIG. 8, insulating layers 106 are formed on a sidewall of the third pillar-like portion 130 on the first mirror 102, a sidewall of the second pillar-like portion 132 on the third mirror 118, and a sidewall of the first pillar-like 134 on the first contact layer 111.

The insulating layer 106 may be obtained by curing liquid material (for example, a precursor such as ultraviolet curable resin and thermosetting resin) curable by energy such as heat or light. The ultraviolet curable resin includes ultraviolet curable acryl-series resin and epoxy-series resin, for example. The thermosetting resin includes thermosetting polyimide-series resin, for example. In addition, the insulating layer 106 may be formed with an inorganic dielectric film such as a silicon oxide film or a silicon nitride film. Further, the insulating layer 106 may be formed with a laminated layer having the materials laminated in plural. Furthermore, the insulating layers 106 having different materials of the above-mentioned materials may be formed on the sidewall of the third pillar-like portion 130, the sidewall of the second pillar-like portion 132, and the sidewall of the first pillar-like 134.

Here, a case where a polyimide-series resin precursor is used as a formation material of the insulating layer 106 will be described. First, a precursor layer is formed by coating a precursor (polyimide-series resin precursor) on the semiconductor substrate 101 using a spin coat method. A forming method of the precursor layer includes a dipping method, a spray coat method, a liquid droplet-jet method, etc., which are well known in the art, in addition to the spin coat method.

Next, after removing a solvent by heating the semiconductor substrate 101 using a hot plate, for example, the semiconductor substrate 101 is put in a furnace of about 400° C. for several hours, for example, in order to imidize the precursor layer such that a nearly completely cured polyimide-series resin layer is formed. Subsequently, as shown in FIG. 8, the insulating layer 106 is formed by patterning the polyimide-series resin layer using a conventional lithography process. An etching process employable for the patterning may include a dry etching process. The dry etching process can be conducted using plasma including oxygen or argon, for example.

In the formation method of the insulating layer 106, although an example where a patterning is conducted after the polyimide-series resin precursor is cured has been described, the patterning may be conducted before the polyimide-series resin precursor is cured. An etching process employable for the patterning may include a wet etching process. The wet etching process can be conducted using alkali solution or organic solution, for example.

In addition, when the silicon nitride film is used as the insulating layer 106, the insulating layer 106 can be formed by a plasma CVD method, for example. More specifically, the insulating layer 106 can be formed at temperature of about 350° C. in plasma including silane (SiH₄), ammonia (NH₃) and nitrogen (N₂) as material gases.

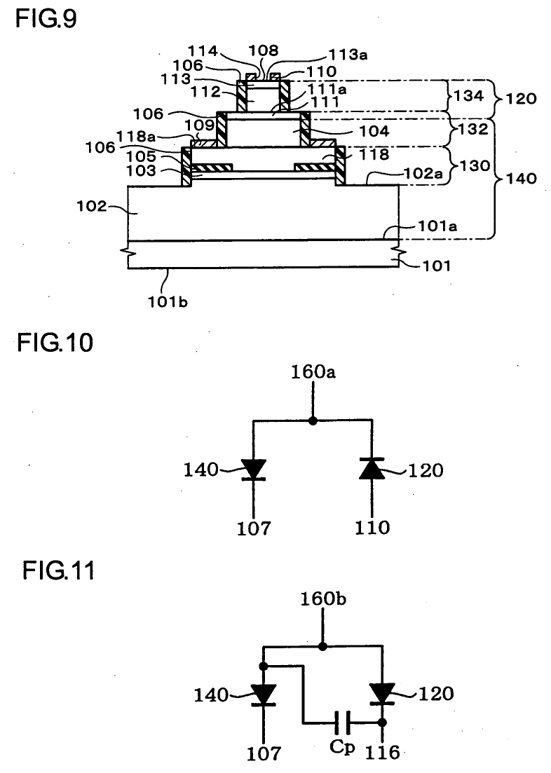

(7) Next, the second electrode 109 is formed on the top surface 118a of the third mirror 118 and the fourth electrode 110 is formed on the top surface of the photo-detector 120 (the top surface 113a of the second contact layer 113) (See FIG. 9).

Before forming the second and fourth electrodes 109 and 110, the top surface 118a of the third mirror 118 and the top surface 113a of the second contact layer 113 are first cleaned using a plasma process, if necessary. By doing so, a device having more stable characteristics can be formed.

Next, for example, a lamination film (not shown) of platinum (Pt) and gold (Au) is formed using a vacuum deposition method, a sputtering method, or an electroplating method, for example. Next, the second and fourth electrodes 109 and 110 are formed by removing the lamination layer except for a predetermined position using a lift off method or a dry etching method, for example. At this time, a portion where the lamination layer is not formed is formed on the top surface 113a of the second contact layer 113. This portion becomes an opening 114, and the top surface 113a of the second contact layer 113 exposed through the opening 114 becomes the output surface 108.

Although the second and fourth electrodes 109 and 110 are simultaneously patterned in the above process, they may be formed separately. Although a case where the lamination layer of platinum (Pt) and gold (Au) is formed has been described in the above description, a lamination layer of an alloy of gold (Au) and zinc (Zn), and gold (Au), for example, may be formed. In addition, for reinforcement of adherence of the electrodes and prevention of diffusion due to electrode material, chromium (Cr), titanium (Ti), nickel (Ni), etc. may be laminated.

Next, an annealing process is conducted. Temperature of the annealing process depends on electrode material. For the electrode material used in this embodiment, the annealing temperature is typically about 400° C. However, the annealing process in this process (the process for forming the second and fourth electrodes 109 and 110) may be omitted by conducting the annealing process in a process for forming the first and third electrodes 107 and 116, which will be described later.

(8) Next, in a similar way, by patterning a lamination layer of an alloy of gold (Au) and germanium (Ge), and gold (Au), for example, the first electrode 107 is formed on the first mirror 102 of the light-emitting device 140 and the third electrode 116 is formed on the first contact layer 111 of the photo-detector 120 (See FIG. 1). Next, an annealing process is conducted. Temperature of the annealing process depends on electrode material. For the electrode material used in this embodiment, the annealing temperature is typically about 400° C. Through the above processes, the first and third electrodes 107 and 116 are formed.

Although the first and third electrodes 107 and 116 are simultaneously patterned in the above process, they may be formed separately. Although a case where the lamination layer of an alloy of gold (Au) and germanium (Ge), and gold (Au) is formed has been described in the above description, a lamination layer of germanium (Ge) and gold (Au), for example, may be formed. In addition, for reinforcement of adherence of the electrodes and prevention of diffusion due to electrode material, chromium (Cr), titanium (Ti), nickel (Ni), etc. may be laminated.

Through the above processes, the surface-emitting laser 100 including the light-emitting device 140 and the photo-detector 120 can be obtained (See FIGS. 1 and 2).

4. Operation and Effect

The surface-emitting laser 100 according to this embodiment has operation and effects as below.

In the surface-emitting laser 100 according to this embodiment, the second mirror 104 is formed between the light-emitting device 140 and the photo-detector 120. The second mirror 104 is a multi-layered mirror of which at least one of layers composing the unit period is a dielectric layer. In this embodiment, the unit period of the second mirror 104 is configured by an Al_{0.2}Ga_{0.8}As layer and the dielectric layer (layer containing aluminum oxide). Accordingly, the light-emitting device 140 can be isolated from the photo-detector 120 by the second mirror 104. That is, in the surface-emitting semiconductor laser 100 according to this embodiment, the second mirror 104 can act as the multi-layered mirror required for laser oscillation in the light-emitting device 140, and moreover, can act as an isolating layer for isolating the light-emitting device 140 from the photo-detector 120.

In the surface-emitting laser 100 according to this embodiment, the second mirror 104 is formed between the light-emitting device 140 and the photo-detector 120. The second mirror 104 is a multi-layered mirror of which at least one of layers composing the unit period is a dielectric layer. In this embodiment, the unit period of the second mirror 104 is configured by an Al_{0.2}Ga_{0.8}As layer and the dielectric layer (layer containing aluminum oxide). The second mirror 104 includes the Al_{0.2}Ga_{0.8}As layer and the dielectric layer (layer containing aluminum oxide), which are alternately stacked in five pairs. Namely, the period of the second mirror 104 is five.

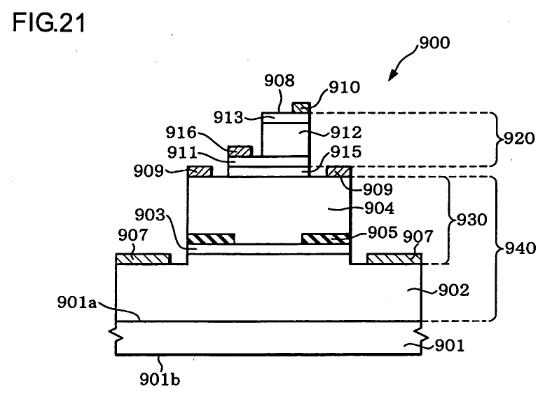

In the conventional surface-emitting laser 900, for example, as shown in FIG. 21, which is described in the above background art, the electrostatic capacity of the dielectric layer 915 is 0.46 pF. This is a result obtained when the electrostatic capacity is calculated in the case where the dielectric layer 915 is a layer (having relative permittivity of 9.5) containing the aluminum oxide, the diameter of the dielectric layer 915 is 30 μm when viewed from a plane, and the thickness of the dielectric layer 915 is 0.13 μm.

Assuming that ε₀ is vacuum permittivity, εᵣ is relative permittivity of a dielectric layer, S is an area of the dielectric layer when viewed from a plane, and d is a thickness of the dielectric layer, the electrostatic capacity C is expressed by the following equation.
C=ε₀εᵣ(S/d)

However, with the surface-emitting laser 100 according to present invention, the electrostatic capacity of the second mirror 104 is 0.068 pF. This is a result obtained when the second mirror 104 is composed of an Al_{0.2}Ga_{0.8}As layer (having relative permittivity of 13) having the film thickness of 0.06 μm and a layer (having relative permittivity of 9.5) having the film thickness of 0.13 μm and containing aluminum oxide, which are alternately stacked in five pairs, the diameter of the second mirror 104 is 30 μm when viewed from a plane, and electrostatic capacities of layers are connected in series. At this time, the total film thickness of the second mirror 104 is 0.95 μm. Namely, it is preferable that the film thickness of the second mirror 104 is more than 0.9 μm. Accordingly, the electrostatic capacity of the second mirror 104 can be significantly reduce, which will be described later.

Arranging the result of the above calculation, while the electrostatic capacity of the dielectric layer 915 in the conventional surface-emitting laser 900 is 0.46 pF, for example, as shown in FIG. 21, the electrostatic capacity of the second mirror 104 in the surface-emitting laser 100 according to this embodiment is 0.068 pF. That is, the electrostatic capacity of the second mirror 104 in the surface-emitting laser 100 according to present invention can be significantly reduced, compared to the electrostatic capacity of the dielectric layer 915 in the conventional surface-emitting laser 900, for example, as shown in FIG. 21. More specifically, with the surface-emitting laser 100 according to this embodiment, the electrostatic capacity can be reduced by a single digit or so, for example. Accordingly, parasite capacitance occurring between the light-emitting device 140 and the photo-detector 120 can be reduced. As a result, the surface-emitting laser 100 can be operated at a high speed.

With the surface-emitting laser 100 according to this embodiment, the film thickness of the dielectric layer can become so small that reliability and mechanical strength of the dielectric layer can be secured, and the parasite capacitance occurring between the light-emitting device 140 and the photo-detector 120 can be further reduced, compared to the conventional surface-emitting laser 900 as shown in FIG. 21, for example. That is, with the surface-emitting laser 100 according to this embodiment, while maintaining the reliability and mechanical strength, the parasite capacitance occurring between the light-emitting device 140 and the photo-detector 120 can be further reduced, compared to the conventional surface-emitting laser 900 as shown in FIG. 21, for example.

In the surface-emitting laser 100 according to this embodiment, the third mirror 118 is provided on the active layer 103, and the second mirror 104 is provided on the third mirror 118. In addition, the second electrode 109 is provided on the third mirror 118. That is, since the second electrode 109 is provided in closer proximity to the active layer 103, compared to a case where the second electrode 109 is provided on the second mirror 104, a voltage can be more effectively applied to the active layer 103.

In the surface-emitting laser 100 according to this embodiment, the second mirror 104 is provided on the third mirror 118, and the second electrode 109 is provided on the second mirror 104. In addition, the second mirror 104 is a multi-layered mirror, and at least one of layers composing the unit period of the second mirror is a dielectric layer. Accordingly, current does not flow into the second mirror 104. That is, carriers do not move in the second mirror 104, but moves in only the third mirror 118. Accordingly, since the carriers can move in the surface-emitting laser 100 via the less number of hetero junctions, the surface-emitting laser 100 having lower resistance can be attained. As a result, the surface-emitting laser 100 can be operated at a higher speed. In addition, temperature of devices in the surface-emitting laser 100 can be prevented from rising.

In general surface-emitting lasers, impurities are added in mirrors in order to lower resistance of the mirrors. However, the addition of the impurities may cause irregularity in light absorption or Auger recombination, which may result in deterioration of luminous efficiency. On the contrary, in the surface-emitting laser 100 according to this embodiment, impurities may not be added in the second mirror 104. Accordingly, the problem of the addition of impurities can be overcome.

In addition, in the surface-emitting laser 100 according to this embodiment, the second mirror 104 is formed in a pillar shape and the sidewall of the second mirror 104 is covered with the insulating layer 106. Accordingly, the mechanical strength of the second mirror 104 can be enhanced. In addition, since an external atmosphere (for example, oxygen, vapor, etc.) is intercepted by the insulating layer 106, the reliability of the surface-emitting laser 100 can be enhanced.

5. Modification

The surface-emitting laser 100 according to this embodiment can have a three-terminal structure by electrically connecting one of the first and second electrodes 107 and 109 of the light-emitting device 140 to one of the third and fourth electrodes 116 and 110 of the photo-detector 120 at an electrode junction.

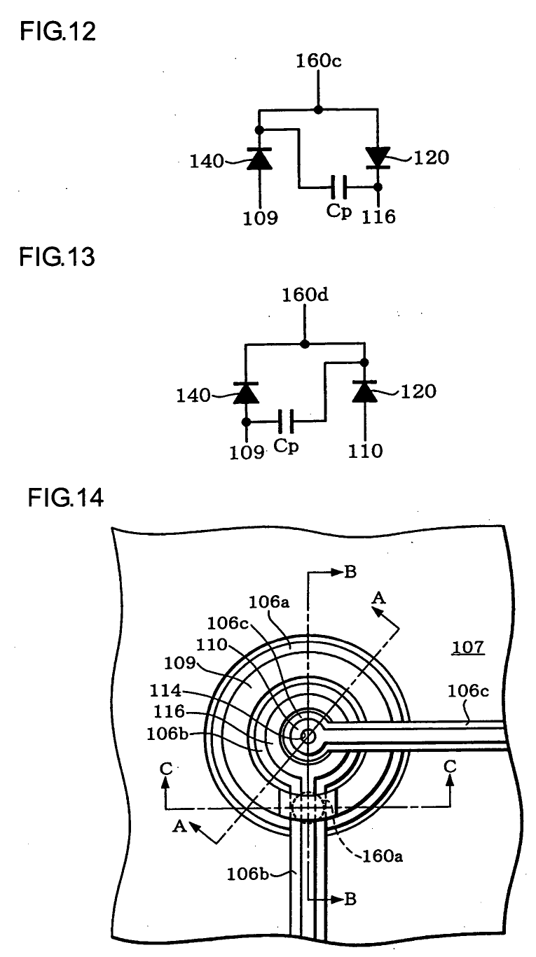

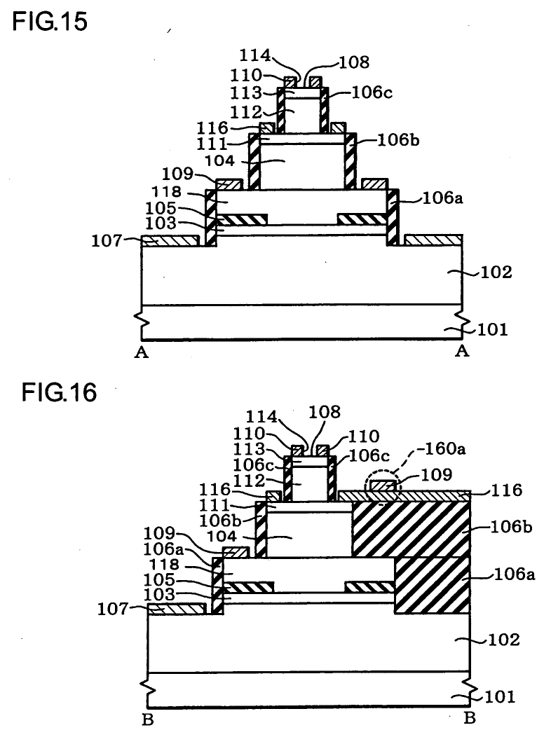

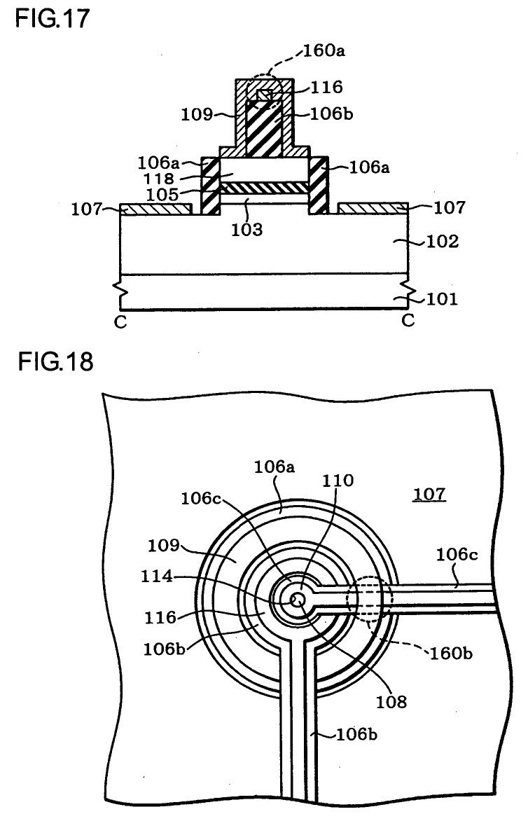

Method of connecting the electrodes each other when the surface-emitting laser 100 has the three-terminal structure are shown in FIGS. 10 to 13. In addition, electrode connection structures for implementing the methods of connecting the electrodes as shown in FIGS. 10 to 13 are schematically shown in plan views of FIGS. 14, and 18 to 20, respectively. In addition, sectional views taken along line A-A, B-B, and C-C in the plan view of FIG. 14 are shown in FIGS. 15 to 17, respectively.

There are four methods for electrically connecting one of the first and second electrodes 107 and 109 of the light-emitting device 140 to one of the third and fourth electrodes 116 and 110 of the photo-detector 120, which are shown as connection methods 1 to 4 in FIGS. 10 to 13, respectively. Electrode junctions 160a to 160d are shown in FIGS. 10 to 13, respectively.

5-1. Connection Method 1

In connection method 1, the second electrode 109 of the light-emitting device 140 is electrically connected to the third electrode 116 of the photo-detector 120 at the electrode junction 160a, as shown in FIGS. 10, and 14 to 17. More specifically, as shown in FIGS. 14 to 17, the electrode junction 160a is provided between the surface-emitting laser 100 and an electrode pad (not shown), and the second and third electrodes 109 and 116 are electrically connected to each other at the electrode junction 160a. That is, the second electrode 109 is provided on the third electrode 116 at the electrode junction 160a.

The third electrode 116 extends from the first contact layer 111 to the insulating layer 106b of the photo-detector 120, and the second electrode 109 extends from the third mirror 118, through the insulating layer 106a, to the insulating layer 106b and the second electrode 109. In addition, the insulating layers 106a, 106b, and 106c may be formed integrally or separately. This is also true of the connection methods 2 to 4, which will be described later. Sectional views of the connection method 2 to 4 are omitted. Parts other than the electrodes, which will be described below, have the same layer structure as the surface-emitting laser 100 shown in FIGS. 14 to 17.

5-2. Connection Method 2

In connection method 2, the second electrode 109 of the light-emitting device 140 is electrically connected to the fourth electrode 110 of the photo-detector 120 at the electrode junction 160b, as shown in FIG. 18. The electrode junction 160b is provided between the surface-emitting laser 100 and an electrode pad (not shown). The second electrode 109 is provided on the fourth electrode 110 at the electrode junction 160b.

The fourth electrode 110 extends from the second contact layer 113 to the insulating layer 106c, and the second electrode 109 extends from the third mirror 118, through the insulating layer 106c, to the fourth electrode 110.

5-3. Connection Method 3

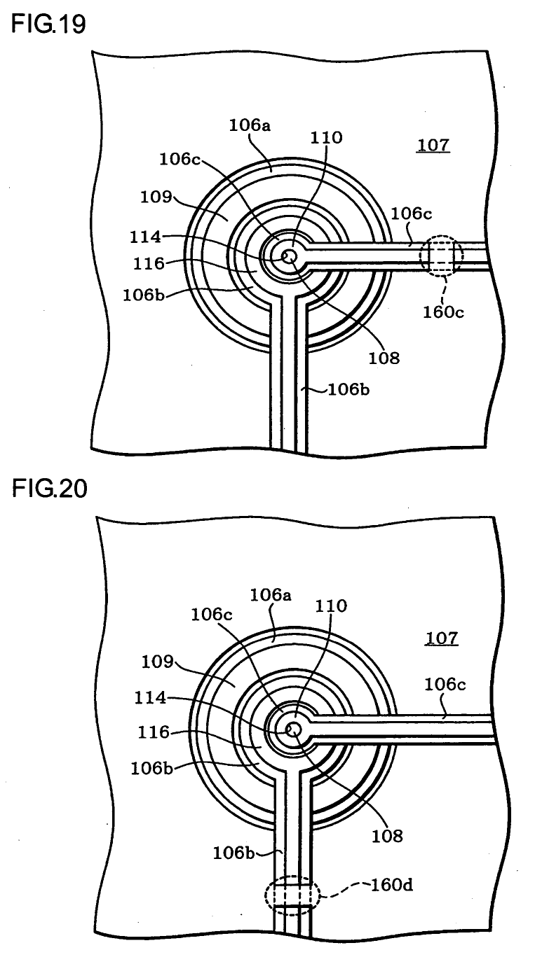

In connection method 3, the first electrode 107 of the light-emitting device 140 is electrically connected to the fourth electrode 110 of the photo-detector 120 at the electrode junction 160c, as shown in FIG. 19. The electrode junction 160c is provided in a region except the light-emitting device 140 and the photo-detector 120 between the surface-emitting laser 100 and an electrode pad (not shown). The first electrode 107 is provided on the fourth electrode 110 at the electrode junction 160c.

The fourth electrode 110 extends from the second contact layer 113 to the insulating layer 106c, and the first electrode 107 extends from the first mirror 102, through the insulating layer 106c, to the fourth electrode 110.

5-4. Connection Method 4

In connection method 4, the first electrode 107 of the light-emitting device 140 is electrically connected to the third electrode 116 of the photo-detector 120 at the electrode junction 160d, as shown in FIG. 20. The electrode junction 160d is provided between the surface-emitting laser 100 and an electrode pad (not shown). The first electrode 107 is provided on the third electrode 116 at the electrode junction 160d.

The third electrode 116 extends from the first contact layer 111 to the insulating layer 106b, and the first electrode 107 extends from the first mirror 102, through the insulating layer 106b, to the third electrode 116.

5-5. Operation and Effect

In connection method 1, the second electrode 109 of the light-emitting device 140 is electrically connected to the third electrode 116 of the photo-detector 120, as shown in FIG. 10. In this case, since a potential difference does not occur between the second electrode 109 and the third electrode 116, the parasite capacitance does not occur between the light-emitting device 140 and the photo-detector 120.

In connection method 2, the second electrode 109 of the light-emitting device 140 is electrically connected to the fourth electrode 110 of the photo-detector 120, as shown in FIG. 11. In this case, since a potential difference occurs between the second electrode 109 and the fourth electrode 110, the parasite capacitance Cₚ occurs.

In connection methods 3 and 4, similarly, when a potential difference occurs between the first electrode 107 and the fourth electrode 110 and between the first electrode 107 and the third electrode 116, the parasite capacitance Cₚ occurs.

In the conventional surface emitting laser 900 as shown in FIG. 21, for example, the dielectric layer 915 is provided between the light-emitting device 940 and the photo-detector 920. This dielectric layer 915 is formed by oxidizing the layer containing aluminum (Al), as previously described. The dielectric layer 915 formed by oxidizing the layer containing aluminum (Al) has small mechanical strength, as previously described. Particularly, if the dielectric layer 915 is thickly formed, the mechanical strength of the surface-emitting laser 900 becomes small. On this account, the dielectric layer 915 must be formed to be thin to some degree. However, if the film thickness of the dielectric layer 915 is small, the parasite capacitance Cₚ occurring between the light-emitting device 940 and the photo-detector 920 is increased.

On the contrary, in the surface-emitting laser 100 according to this embodiment, as described in ‘4. operation and effect’, the electrostatic capacity of the second mirror 104 in the surface-emitting laser 100 according to this embodiment can be significantly reduced, compared to the electrostatic capacity of the dielectric layer 915 in the conventional surface-emitting laser 900 as shown in FIG. 21, for example. Accordingly, since the parasite capacitance Cₚ can be suppressed using the above-described connection methods 2 to 4, the surface-emitting laser 100 can be operated at a high speed.

As described above, any of connection methods 1 to 4 is applicable to the surface-emitting laser according to this embodiment. Accordingly, since the connection method of each electrode can be changed without changing the stack structure of the surface-emitting laser 100, it is possible to attain a high-speed surface-emitting laser 100 with the three-terminal structure, which has some degrees of freedom in its structure. In addition, without changing manufacturing processes other than the electrode forming process, it is possible to attain the surface-emitting laser 100 with the three-terminal structure having different electrode connection methods.

Although the preferred embodiment of the present invention has been described, the present invention is not limited to this, but may be implemented in various ways. For example, in the preferred embodiment, p-type and n-type semiconductor layers may be exchanged without deviating from the scope and spirit of the present invention. In this case, the first mirror 102 of the p-type and the third mirror 118 of the n-type of the light-emitting device 140, and the first contact layer 111 of the p-type and the second contact layer 113 of n-type of the photo-detector 120 can entirely compose a pnpn structure.

In addition, although the unit period of the second mirror 104 in the surface-emitting laser 100 according to the preferred embodiment is composed of two layers of the undoped Al_{0.2}Ga_{0.8}As layer and the dielectric layer, the number of layers in the unit period of the second mirror 104 is not particularly limited if only the unit period has at least one dielectric layer.

In addition, although the light-emitting device 140 includes the third pillar-like portion 130 and a part of the second pillar-like portion 132, for example, in the surface-emitting laser 100 according to the preferred embodiment, the number of pillar-like portions in the light-emitting device 140 is not particularly limited. In addition, although the photo-detector 120 includes the first pillar-like portion 134 and a part of the second pillar-like portion 132, for example, in the surface-emitting laser 100 according to the preferred embodiment, the number of pillar-like portions in the photo-detector 120 is not particularly limited. In addition, a plurality of surface-emitting semiconductor lasers in array has the same operation and effect.

Further, although the AlGaAs series have been mainly used in the preferred embodiment, for example, other material, such as GaInP series, ZnSSe series, InGaN series, AlGaN series, InGaAs series, GaInNAs series, and GaAsSb series, may be used depending on oscillation wavelengths.

1. A surface-emitting semiconductor laser, comprising:
a light-emitting device; and
a photo-detector formed on the light-emitting device,
wherein the light-emitting device comprises a first mirror, an active layer formed on the first mirror, and a second mirror formed on the active layer, the second mirror is a multi-layered film, and at least one of the layers composing a unit period of the second mirror is a dielectric layer.

2. The surface-emitting semiconductor laser according to claim 1,
wherein a third mirror is formed between the active layer and the second mirror, and the third mirror is a multi-layered mirror composed of a semiconductor layer.

3. The surface-emitting semiconductor laser according to claim 2,
wherein the dielectric layer is a layer containing aluminum oxide, the at least one of the layers composing the unit period of the second mirror is an AlGaAs layer, and the third mirror includes at least two AlGaAs layers whose Al compositions are different from each other.

4. The surface-emitting semiconductor laser according to claim 2, further comprising a first electrode and a second electrode for driving the light-emitting device,
wherein the second electrode contacts with the third mirror.

5. The surface-emitting semiconductor laser according to claim 2,
wherein the film thickness of the second mirror is more than 0.9 μm.

6. The surface-emitting semiconductor laser according to claim 3,
wherein the Al composition of the AlGaAs layer composing the second mirror is less than 0.8.

7. The surface-emitting semiconductor laser according to claim 2,
wherein the second mirror has a pillar shape, and a sidewall of the second mirror is covered with an insulating layer.

8. The surface-emitting semiconductor laser according to claim 7,
wherein the insulating layer is made of a resin.

9. The surface-emitting semiconductor laser according to claim 2,
wherein the third mirror has a current limitation layer.

10. The surface-emitting semiconductor laser according to claim 1,
wherein the photo-detector comprises:
a first contact layer;
a light absorbing layer formed on the first contact layer; and
a second contact layer formed on the light absorbing layer.

11. The surface-emitting semiconductor laser according to claim 4, further comprises a third electrode and a fourth electrode for driving the photo-detector.

12. The surface-emitting semiconductor laser according to claim 11,
wherein one of the first electrode and the second electrode is electrically connected to one of the third electrode and the fourth electrode at an electrode junction.

13. The surface-emitting semiconductor laser according to claim 12,
wherein the electrode junction is formed in a region extending to an electrode pad, except for the light-emitting device and the photo-detector.

14. A method of manufacturing a surface-emitting semiconductor laser including a light-emitting device and a photo-detector formed on the light-emitting device and having an output surface, the method comprising:
a step of, on a substrate, laminating semiconductor layers to form at least a first mirror, an active layer, a second mirror composed of a multi-layered film, a first contact layer, a light absorbing layer, and a second contact layer;
a step of forming a first pillar-like portion including at least a part of the second contact layer by etching the semiconductor layers;
a step of forming a second pillar-like portion including at least a part of the second mirror by etching the semiconductor layers; and
a step of forming a dielectric layer by oxidizing at least one of the semiconductor layers composing a unit period of the second mirror from a sidewall of the at least one of the semiconductor layers.

15. The method according to claim 14,
wherein the dielectric layer is formed by oxidizing an AlAs layer or an AlGaAs layer in the second mirror from a sidewall of the AlAs layer or the AlGaAs layer.

16. The method according to claim 14,
wherein the step of laminating semiconductor layers includes a step of laminating other semiconductor layers to form a third mirror composed of a multi-layered film between the active layer and the second mirror, and
the method further comprises a step of forming a third pillar-like portion including at least a part of the third mirror by etching the other semiconductor layers.

17. The method according to claim 16, further comprising a step of forming a current limitation layer by oxidizing the semiconductor layers in the third mirror from sidewalls of the semiconductor layers.

18. The method according to claim 17,
wherein the step of forming the dielectric layer and the step of forming the current limitation layer are performed by the same process.

19. The method according to claim 14, further comprising a step of forming an insulating layer to cover a sidewall of the second pillar-like portion.
